(19) United States
(12) Patent Application Publication
(10) Pub. No.: US 2024/0417557 A1
(43) Pub. Date: Dec. 19, 2024

(54) RESIN COMPOSITION

(71) Applicant: NAN YA PLASTICS CORPORATION, TAIPEI (TW)

(72) Inventors: Te-Chao Liao, TAIPEI (TW); Wei-Ru Huang, TAIPEI (TW); Hung-Yi Chang, TAIPEI (TW); Chia-Lin Liu, TAIPEI (TW)

(73) Assignee: NAN YA PLASTICS CORPORATION, TAIPEI (TW)

(21) Appl. No.: 18/357,167

(22) Filed: Jul. 24, 2023

(30) Foreign Application Priority Data
Jun. 14, 2023 (TW) 112122109

(51) Int. Cl. C08L 25/06; C08K 13/06; C08L 25/16; C08L 71/12

(52) U.S. Cl. CPC C08L 25/06; C08K 13/06; C08L 25/16; C08L 71/126; C08K 5/01; C08K 5/5313; C08K 9/04; C08K 2201/006; C08K 2201/014; C08L 2201/02; C08L 2205/03; C08L 2312/02

(57) ABSTRACT

The invention provides a resin composition that may effectively increase glass transition temperature while maintaining low-k electrical specification. The resin composition includes a first resin polymerized by a monomer mixture including styrene, divinylbenzene, and ethylene, a second resin including a bismaleimide-modified polyphenylene ether resin, a divinylbenzene crosslinking agent, a halogen-free flame retardant, a spherical silica, and a siloxane coupling agent.

### CROSS-REFERENCE TO RELATED APPLICATION

This application claims the priority benefit of Taiwan application serial no. 112122109, filed on Jun. 14, 2023. The entirety of the above-mentioned patent application is hereby incorporated by reference herein and made a part of this specification.

### BACKGROUND OF THE INVENTION

### Field of the Invention

The invention relates to a resin, and in particular to a low-k resin composition.

### Description of Related Art

In recent years, with the development of 5G communication, copper-clad laminate materials have been developed towards the object of lower dielectric (low-k) properties. The dielectric constant (Dk) of the current substrate is about 3.2 to 5.0, which is not conducive to the application of high frequency and fast transmission in the future. In the current low-k formula, a certain proportion of new low-k resin (poly-DVB, hereinafter referred to as the first resin) may be added to reduce the electrical properties until the dissipation factor (Df) is less than 0.0015. However, while achieving the low electrical specification, low glass transition temperature (Tg) and/or poor fluidity may occur, resulting in a decrease in overall processability.

Therefore, the development of a resin composition that may increase glass transition temperature and/or improve fluidity while maintaining low-k electrical specification, so as to achieve good processability of the resin composition, is an object that the industry is eager to achieve.

### SUMMARY OF THE INVENTION

The invention provides a resin composition having the effect of increasing glass transition temperature while maintaining low-k electrical specification.

The resin composition of the invention includes a resin base, a halogen-free flame retardant, a spherical silica, and a siloxane coupling agent. The resin base includes a first resin, a second resin, and a divinylbenzene crosslinking agent. The first resin is polymerized from a monomer mixture including styrene, divinylbenzene, and ethylene. The second resin includes a bismaleimide-modified polyphenylene ether resin.

In an embodiment of the invention, based on 100 parts by weight of the resin base, a content of the first resin is 30 parts by weight to 60 parts by weight, a content of the second resin is 20 parts by weight to 40 parts by weight, and a content of the divinylbenzene crosslinking agent is 10 parts by weight to 30 parts by weight.

In an embodiment of the invention, based on 100 parts by weight of the resin base, an addition amount of the halogen-free flame retardant is 20 phr to 50 phr.

In an embodiment of the invention, based on a weight sum of 100 parts by weight of the resin base and the halogen-free flame retardant, an addition amount of the spherical silica is 20 parts by weight to 50 parts by weight.

In an embodiment of the invention, a molar ratio of styrene: divinylbenzene: ethylene in the first monomer mixture is 1:1:1 to 2:2:1.

In an embodiment of the invention, a number-average molecular weight of the first resin is 4500 to 6500.

In an embodiment of the invention, the resin base further includes an SBS resin polymerized from a second monomer mixture including styrene, 1,2-butadiene, and 1,4-butadiene.

In an embodiment of the invention, a molar ratio of styrene: 1,2-butadiene: 1,4-butadiene in the second monomer mixture is 1:6:4 to 4:9:3.

In an embodiment of the invention, based on 100 parts by weight of the resin base, a content of the SBS resin is 0 parts by weight to 30 parts by weight.

In an embodiment of the invention, a weight-average molecular weight of the SBS resin is 3500 to 5500.

In an embodiment of the invention, the spherical silica has an acrylic or vinyl surface modification, and has an average particle size D50 of 2.0 microns to 3.0 microns.

In an embodiment of the invention, an electrical specification of the resin composition is a dielectric constant of 3.0 to 3.1 and a dissipation factor of less than 0.0015, and a heat resistance specification of the resin composition is a glass transition temperature of greater than 210° C.

Based on the above, the resin composition of the invention may be made to have low-k electrical specification via the combination of the first resin (polymerized from the monomer mixture including styrene, divinylbenzene, and ethylene) and the second resin (including bismaleimide-modified polyphenylene ether resin). Moreover, by introducing the cross-linking agent containing divinylbenzene, low-k electrical specification may be maintained, and at the same time, glass transition temperature is increased and fluidity is improved, thereby improving overall processability.

### DESCRIPTION OF THE EMBODIMENTS

Hereinafter, embodiments of the invention are described in detail. However, these embodiments are illustrative, and the disclosure of the invention is not limited thereto.

Herein, a range indicated by “one value to another value” is a general representation which avoids enumerating all values in the range in the specification. Therefore, the recitation of a specific numerical range covers any number within this numerical range and any smaller numerical range bounded by any number within that numerical range as if such any number and such smaller numerical ranges were expressly written in the specification.

A resin composition of the invention includes a resin base, a halogen-free flame retardant, a spherical silica, and a siloxane coupling agent. In particular, the resin base includes a first resin, a second resin, and a crosslinking agent. The first resin is polymerized from a monomer mixture including styrene, divinylbenzene, and ethylene. Moreover, the second resin includes a bismaleimide-modified polyphenylene ether resin. The crosslinking agent is divinylbenzene. Hereinafter, the above various components are described in detail.

### Resin Base

In the invention, the resin base is the resin component in the resin composition, including a first resin, a second resin, an SBS resin, and a cross-linking agent between the polymerized resins. The above components are described below.

### [First Resin]

In the present embodiment, the first resin may be polymerized from a first monomer mixture including styrene, divinylbenzene, and ethylene. In the first monomer mixture, the molar ratio of styrene: divinylbenzene: ethylene is 1:1:1 to 2:2:1. That is, the first resin has a styrene group ratio of 10% to 40%, a divinylbenzene group ratio of 10% to 40%, and a vinyl group ratio of 10% to 20%. In some embodiments, the number-average molecular weight (Mn) of the first resin may be about 4500 to 6500. In some embodiments, based on 100 parts by weight of the resin base, the content of the first resin is, for example, 30 parts by weight to 60 parts by weight, preferably, for example, 35 parts by weight to 45 parts by weight. Adding the first resin to the resin composition may effectively reduce the dielectric constant (Dk) and the dissipation factor (Df) of the resin composition, so as to achieve low-k electrical specification.

### [Second Resin]

In the present embodiment, the second resin may include bismaleimide (BMI)-modified polyphenylene ether (PPE) resin. For example, the second resin of the invention may be bismaleimide-modified polyphenylene ether resin (PPE-BMI) disclosed in Taiwan Patent Publication No. 1774559. The disclosure of Taiwan Patent Publication No. 1774559 is incorporated herein by reference in its entirety.

For example, the chemical structure of the bismaleimide-modified polyphenylene ether resin may be represented by the following chemical formula:

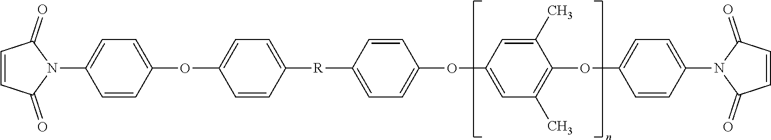

wherein R may be, for example: direct bond, methylene, ethylene, isopropylene, 1-methylpropylene, pyrenylene, or fluorenylene,
n may be an integer between 3 and 25, preferably an integer between 10 and 18.

The bismaleimide-modified polyphenylene ether resin may be formed by the manufacturing method disclosed in Taiwan Patent Publication No. 1774559, but the invention is not limited thereto. The bismaleimide-modified polyphenylene ether resin may also be formed, for example, by other suitable modification methods.

In some embodiments, based on 100 parts by weight of the resin base, the content of the second resin is, for example, 20 parts by weight to 40 parts by weight, preferably, for example, 30 parts by weight to 40 parts by weight, but not limited thereto. Since the chemical structure of the second resin has both a main chain of polyphenylene ether and a terminal modified with a highly heat-resistant reactive group (i.e., bismaleimide), the second resin has a relatively low dielectric constant and a relatively low dissipation factor.

### [SBS Resin]

In the present embodiment, the SBS resin refers to a styrene-butadiene-styrene block copolymer (SBS). The SBS resin may be polymerized from a second monomer mixture including styrene, 1,2-butadiene, and 1,4-butadiene. In the second monomer mixture, the molar ratio of styrene: 1,2-butadiene: 1,4-butadiene may be 1:6:1 to 4:9:3. That is, the SBS resin has a styrene group ratio of 10% to 40%, a 1,2-butadiene group ratio of 60% to 90%, and a 1,4-butadiene group ratio of 10% to 30%. The SBS resin has a weight-average molecular weight (Mw) of about 3500 to 5500. In some embodiments, based on 100 parts by weight of the resin base, the content of the SBS resin is, for example, 0 parts by weight to 30 parts by weight, but not limited thereto. Adding the SBS resin to the resin composition may alleviate phase separation between the resins, improve fluidity and filling properties, thereby enhancing overall processability while maintaining low-k properties.

### [Crosslinking Agent]

The crosslinking agent is used to increase the degree of crosslinking of the thermosetting resin, adjust rigidity and toughness of the substrate, and adjust processability. Common crosslinking agents are, for example, a combination of one or more than one of, for example, 1,3,5-triallyl cyanurate (TAC), triallyl isocyanurate (TAIC), trimethallyl isocyanurate (TMAIC), diallyl phthalate, divinylbenzene, or 1,2,4-triallyl trimellitate. In the invention, the crosslinking agent includes at least a divinylbenzene (DVB) crosslinking agent. In some embodiments, based on 100 parts by weight of the resin base, the content of the divinylbenzene crosslinking agent is, for example, 10 parts by weight to 40 parts by weight, preferably, for example, 10 parts by weight to 30 parts by weight. By introducing the divinylbenzene crosslinking agent into the resin composition, low-k electrical specification may be maintained, and at the same time, glass transition temperature may be increased and fluidity of the resin may be improved, thereby improving overall processability.

### Halogen-Free Flame Retardant

In the present embodiment, specific examples of the halogen-free flame retardant may be a phosphorous flame retardant selected from phosphate ester, such as: triphenyl phosphate (TPP), resorcinol diphosphate (RDP), bisphenol A bis(diphenyl) phosphate (BPAPP), bisphenol A bis(dimethyl) phosphate (BBC), resorcinol diphosphate (CR-733S), resorcinol-bis(di-2,6-dimethylphenyl phosphate) (PX-200); and may be selected from phosphazene, such as: polydi (phenoxy)phosphazene (SPB-100); ammonium polyphosphate, melamine phosphate (MPP), melamine cyanurate; and may be selected from a combination of one or more of DOPO flame retardants such as DOPO (such as Structural formula C), DOPO-HQ (such as Structural formula D), double DOPO derived structures (such as Structural formula E), etc.; aluminum-containing hypophosphite lipids (such as Structural formula F). In some embodiments, based on 100 parts by weight of the resin base, the addition amount of the halogen-free flame retardant is, for example, 20 phr to 50 phr.

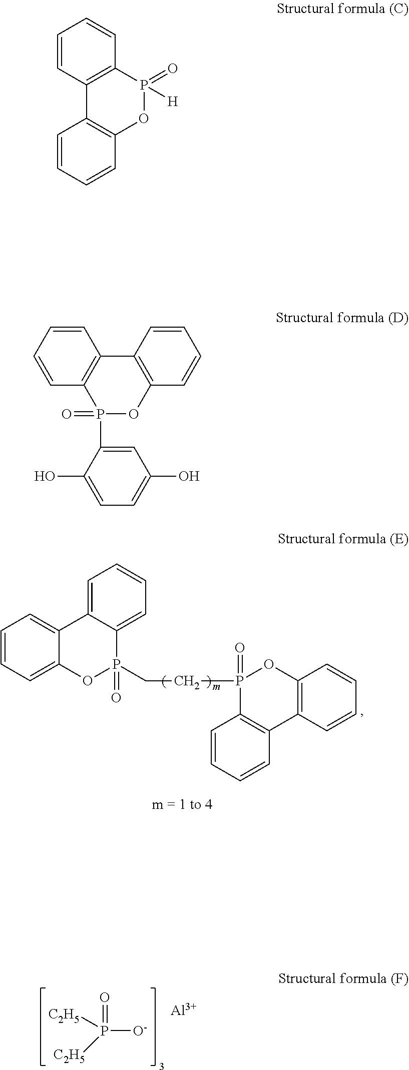

### Spherical Silica

In the present embodiment, the spherical silica may preferably be prepared by a synthetic method to reduce electrical properties and maintain fluidity and filling properties. The spherical silica has acrylic or vinyl surface modification, the purity is 99.0% or more, and the average particle size (D50) is about 2.0 microns to 3.0 microns. In some embodiments, based on a weight sum of 100 parts by weight of the resin base and the halogen-free flame retardant, the addition amount of the spherical silica is 20 parts by weight to 50 parts by weight, for example.

### Siloxane Coupling Agent

In the present embodiment, the siloxane coupling agent may include, but not limited to, siloxane. Moreover, according to the type of functional group, it may be divided into amino silane compound (amino silane), epoxy silane compound (epoxide silane), vinyl silane compound, esteryl silane compound, hydroxysilane compound, isocyanate silane compound, methacryloxysilane compound, and acryloxysilane compound. In some embodiments, based on 100 parts by weight of the resin composition, the addition amount of the siloxane coupling agent is, for example, 0.1 phr to 5 phr. By adding the siloxane coupling agent in the resin composition, compatibility and cross-linking degree to glass fiber cloth and powder may be enhanced.

### Additive

In addition to the above components, the resin composition of the invention may also contain other additives, such as a peroxide initiator.

It should be mentioned that, the resin composition of the invention may be processed into a prepreg and/or copper-clad laminate (CCL) according to actual design requirements. Therefore, the prepreg and the copper-clad laminate manufactured by using the resin composition of the invention also have better reliability (the desired electrical properties can be maintained). In some preferred embodiments, the dielectric constant of the substrate (or prepreg) made of the resin composition is about 3.0 to 3.1, and the dissipation factor is less than about 0.0015, thus achieving ultra-low-k electrical specification, and glass transition temperature may be higher, such as greater than 210° C.

Hereinafter, the resin composition of the invention is described in detail by using experimental examples. However, the following experimental examples are not intended to limit the invention.

### Experimental Examples

In order to prove that the resin composition proposed by the invention may maintain low dielectric constant or/and low dissipation factor and achieve low-k electrical specification while improving fluidity and glass transition temperature of the resin composition, in the following, these Experimental examples are specifically described.

### Preparation of Second Resin

A small molecular weight polyphenylene ether resin material with a number-average molecular weight (Mn) less than or equal to 12,000 or less than or equal to 10,000 (for example, Mn=500, 1400, 1600, or 1800) was dissolved in dimethylacetamide, and then potassium carbonate and tetrafluoronitrobenzene were added. The above reaction solution was heated up to 140° C. and reacted for 8 hours, then cooled down to room temperature, followed by filtration to remove the solid. The filtrate was precipitated using methanol/water, and the precipitate was nitrated polyphenylene ether resin. Then, the nitrated polyphenylene ether resin was dissolved in dimethylacetamide, and hydrogenated at 90° C. for 8 hours to obtain an aminated polyphenylene ether resin. Then, the aminated polyphenylene ether resin was placed in toluene, maleic anhydride and p-toluenesulfonic acid were added therein, the temperature was raised to 120° C. to reflux, and the mixture was reacted for 8 hours to prepare the second resin. The second resin was bismaleimide-modified polyphenylene ether resin (PPE-BMI).

### Preparation of Resin Composition

The resin composition shown in Table 1 was mixed with toluene to form a varnish of a thermosetting resin composition, and the above varnish was impregnated with Nanya fiberglass cloth (Nanya Plastic Company, cloth type 1078LD) at room temperature, then dried at 170° C. (impregnation machine) for several minutes to obtain a prepreg with a resin content of 79% by weight. Lastly, four prepregs were stacked in layers between two copper foils with a thickness of 35 microns. Under a pressure of 25 kg/cm² and a temperature of 85° C., constant temperature was maintained for 20 minutes, then heating was performed to 210° C. at a heating rate of 3° C./min, and then constant temperature was maintained for 120 minutes. Then, cooling was performed slowly to 130° C. to obtain a 0.59 mm thick copper-clad laminate, and various properties were evaluated.

### Evaluation Method

The copper-clad laminates produced in each Example and Comparative example were evaluated according to the following methods, and the results are shown in Table 1.

The glass transition temperature (C) was tested with a dynamic mechanical analyzer (DMA).

Water absorption (%): after heating the sample in a pressure cooker at 120° C. and 2 atm for 120 minutes, the weight change before and after heating was calculated.

Solder heat resistance at 288° C. (seconds): the sample was heated in a 120° C. and 2 atm pressure cooker for 120 minutes, then immersed in a 288° C. solder furnace, and the time needed for the sample to explode and delaminate was recorded.

Dielectric constant Dk: the dielectric constant Dk at a frequency of 10 GHz was tested with dielectric analyzer HP Agilent E4991A.

Dissipation factor Df: the dielectric loss Df at a frequency of 10 GHz was tested with dielectric analyzer HP Agilent E4991A.

Resin flow rate: depression was performed with 200 plus or minus 25 PSI using a press at 170° C. plus or minus 2.8° C. for 10 minutes. After fusion and cooling, a disc was punch out. The weight of the disc was accurately weighed to calculate the outflow of resin.

Resin phase separation (slice analysis):
Step 1: the copper-clad laminate was cut into a size of 1 cm*1 cm, and placed into a mold for resin grouting.
Step 2: after the resin was completely dried and cured, the sample was ground and polished.
Step 3: the sample was analyzed using a high-resolution microscope such as OM/SEM to confirm whether there was resin phase separation inside the sample.

In Table 1, the details of each component are as follows:
First resin: LDM-03 (purchased from Denka Company)
Second resin: the prepared second resin was used
SBS resin: 1,2-SBS Type-C(purchased from Nippon Soda Corporation)
Cross-linking agent DVB: divinylbenzene cross-linking agent
Cross-linking agent TAIC: triallyl isocyanuric acid cross-linking agent
Halogen-free flame retardant: PQ-60 (purchased from Chin Yee Chemical Company)
Silicon dioxide: EQ2410-SMC (purchased from Third Age Technology Company)
Peroxide: Luperox F (purchased from ARKEMA Company)
Siloxane coupling agent: Z-6030 (purchased from Dow Corning)

TABLE 1
Composition and property evaluation of resin compositions of Comparative examples 1 to 3 and Experimental examples 1 to 3

| | | | Comparative | Comparative | Comparative | Experimental | Experimental | Experimental |
|---|---|---|---|---|---|---|---|---|
| | | | example 1 | example 2 | example 3 | example 1 | example 2 | example 3 |
| Resin | (100 parts | First resin (parts | 40 | 40 | 40 | 40 | 40 | 40 |
| composition | by weight) | by weight) | | | | | | |
| | Resin base | Second resin (parts | 40 | 40 | 30 | 40 | 40 | 30 |
| | | by weight) | | | | | | |
| | | SBS resin (parts | 10 | — | — | 10 | — | — |
| | | by weight) | | | | | | |
| | | Cross-linking agent | — | — | — | 10 | 20 | 30 |
| | | DVB (parts by weight) | | | | | | |
| | | Cross-linking agent | 10 | 20 | 30 | — | — | — |
| | | TAIC (parts by weight) | | | | | | |
| | Halogen-free flame retardant (phr) (based | | 30 | 30 | 30 | 30 | 30 | 30 |
| | on 100 parts by weight of resin base) | | | | | | | |
| | Silica (parts by weight) (based on 100 parts | | 40 | 40 | 10 | 40 | 40 | 40 |
| | by weight of resin base + flame retardant) | | | | | | | |
| | Peroxide (phr) (based on 100 parts by | | 1 | 1 | 1 | 1 | 1 | 1 |
| | weight of resin base) | | | | | | | |
| | Siloxane coupling agent (phr) (based on | | 0.5 | 0.5 | 0.5 | 0.5 | 0.5 | 0.5 |
| | 100 parts by weight of resin base) | | | | | | | |
| | B-stage curing temperature (° C.) | | 130 | 130 | 130 | 130 | 130 | 130 |
| | Glass transition temperature (° C.) | | 220 | 232 | 224 | 217 | 241 | 235 |
| | PCT 1/2 | Water absorption (%) | 0.23 | 0.24 | 0.25 | 0.21 | 0.17 | 0.17 |
| | hours | Heat resistance | OK | OK | OK | OK | OK | OK |
| | PCT 2 | Water absorption (%) | 0.26 | 0.27 | 0.29 | 0.26 | 0.24 | 0.23 |
| | hours | Heat resistance | OK | OK | OK | OK | OK | OK |

| | | | | | | |
|---|---|---|---|---|---|---|
| Dielectric Constant (Dk) (frequency 10 GHz) | 3.09 | 3.12 | 3.12 | 3.07 | 3.07 | 3.05 |
| Dissipation factor (Df) (frequency 10 GHz) | 0.00151 | 0.00155 | 0.00158 | 0.00148 | 0.00146 | 0.00144 |
| Resin fluidity (%) | 37 | 41 | 45 | 35 | 38 | 41 |
| Resin phase separation (slice analysis) | No phase | No phase | No phase | No phase | No phase | No phase |
| | separation | separation | separation | separation | separation | separation |

In Table 1, Comparative examples 1 to 3 adopted triallyl isocyanuric acid (TAIC) as the crosslinking agent, and Experimental examples 1 to 3 adopted divinylbenzene (DVB) as the crosslinking agent. The results showed that compared with Comparative examples 1 to 3 adopting the TAIC crosslinking agent, in Experimental examples 1 to 3 adopting the DVB cross-linking agent (Example 1 compared with Comparative example 1, Example 2 compared with Comparative example 2, Example 3 compared with Comparative example 3), glass transition temperature was increased, resin fluidity was improved, and dissipation factor (Df) was reduced while maintaining similar low-k electrical specification.

Based on the above, in the resin composition of the invention, the first resin (polymerized from a monomer mixture including styrene, divinylbenzene, and ethylene) is combined with the second resin (including bismaleimide-modified polyphenylene ether resin). As a result, the resin composition of the present application may have low-k electrical specification (such as low dielectric constant, low dissipation factor), and by introducing the cross-linking agent containing divinylbenzene, the effect of increasing glass transition temperature and improving fluidity while maintaining the electrical properties of the substrate may be achieved, thereby improving overall processability.

Although the invention has been described with reference to the above embodiments, it will be apparent to one of ordinary skill in the art that modifications to the described embodiments may be made without departing from the spirit of the invention. Accordingly, the scope of the invention is defined by the attached claims and not by the above detailed descriptions.

What is claimed is:

1. A resin composition, comprising:
a resin base, comprising:
a first resin polymerized from a first monomer mixture comprising styrene, divinylbenzene, and ethylene;
a second resin comprising a bismaleimide-modified polyphenylene ether resin; and
a divinylbenzene crosslinking agent;
a halogen-free flame retardant;
a spherical silica; and
a siloxane coupling agent.

2. The resin composition of claim 1, wherein based on 100 parts by weight of the resin base, a content of the first resin is 30 parts by weight to 60 parts by weight, a content of the second resin is 20 parts by weight to 40 parts by weight, and a content of the divinylbenzene crosslinking agent is 10 parts by weight to 30 parts by weight.

3. The resin composition of claim 1, wherein based on 100 parts by weight of the resin base, an addition amount of the halogen-free flame retardant is 20 phr to 50 phr.

4. The resin composition of claim 1, wherein based on a weight sum of 100 parts by weight of the resin base and the halogen-free flame retardant, an addition amount of the spherical silica is 20 parts by weight to 50 parts by weight.

5. The resin composition of claim 1, wherein a molar ratio of styrene: divinylbenzene: ethylene in the first monomer mixture is 1:1:1 to 2:2:1.

6. The resin composition of claim 1, wherein a number-average molecular weight of the first resin is 4500 to 6500.

7. The resin composition of claim 1, wherein the resin base further comprises:
an SBS resin polymerized from a second monomer mixture comprising styrene, 1,2-butadiene, and 1,4-butadiene.

8. The resin composition of claim 7, wherein a molar ratio of styrene: 1,2-butadiene: 1,4-butadiene in the second monomer mixture is 1:6:4 to 4:9:3.

9. The resin composition of claim 7, wherein based on 100 parts by weight of the resin base, a content of the SBS resin is 0 parts by weight to 30 parts by weight.

10. The resin composition of claim 7, wherein a weight-average molecular weight of the SBS resin is 3500 to 5500.

11. The resin composition of claim 1, wherein the spherical silica has an acrylic or vinyl surface modification, and has an average particle size of 2.0 microns to 3.0 microns.

12. The resin composition of claim 1, wherein an electrical specification of the resin composition is a dielectric constant of 3.0 to 3.1 and a dissipation factor of less than 0.0015, and a heat resistance specification of the resin composition is a glass transition temperature of greater than 210° C.
